(19) United States
(12) Patent Application Publication
(10) Pub. No.: US 2025/0055210 A1
(43) Pub. Date: Feb. 13, 2025

(54) PRESS-FIT TERMINAL, TERMINAL STRUCTURE, AND SEMICONDUCTOR MODULE

(71) Applicant: FUJI ELECTRIC CO., LTD., Kawasaki-shi (JP)

(72) Inventor: Makoto ISOZAKI, Kawasaki-shi, Kanagawa (JP)

(73) Assignee: FUJI ELECTRIC CO., LTD., Kawasaki-shi (JP)

(21) Appl. No.: 18/932,400

(22) Filed: Oct. 30, 2024

Related U.S. Application Data
(63) Continuation of application No. PCT/JP2023/036714, filed on Oct. 10, 2023.

(30) Foreign Application Priority Data
Nov. 11, 2022 (JP) 2022-180715

(51) Int. Cl. H01R 12/58; H01L 23/498; H01L 25/07

(52) U.S. Cl. CPC H01R 12/585; H01L 23/49811; H01L 23/49838; H01L 25/072

(57) ABSTRACT

A press-fit terminal to be connected to a substrate having a through hole includes a press-fit portion configured to be press-fitted and held inside the through hole; and a fitting portion configured to fit to an outer surface of the substrate outside the through hole and restrict movement of the press-fit terminal in a direction in which the press-fit terminal comes off from the through hole.

### CROSS-REFERENCE TO RELATED APPLICATION

This is a continuation application of International Application PCT/JP2023/036714 filed on Oct. 10, 2023 which claims priority from a Japanese Patent Application No. 2022-180715 filed on Nov. 11, 2022, the contents of which are incorporated herein by reference.

### TECHNICAL FIELD

The present invention relates to a press-fit terminal, a terminal structure, and a semiconductor module.

### BACKGROUND ART

As a means for electrically connecting an electronic component such as a semiconductor element and a circuit board, a structure in which a press-fit terminal provided on the electronic component is press-fitted into a through hole of the circuit board is known. The press-fit terminal includes a press-fit portion having a terminal width and a terminal thickness larger than the hole diameter of the through hole, and is inserted into the through hole in a state where the press-fit portion is deformed to be narrowed. Then, the outer surface of the press-fit portion is pushed against the inner surface of the through hole, causing the press-fit terminal to be held.

If the press-fit terminal is designed so as to have a high press-fit holding force by increasing the terminal width and the terminal thickness to prevent the terminal from coming off from the through hole, the press-fit load (resistance during press-fitting) increases, thus making it more likely that the press-fit terminal will be broken or bent during the insertion. When the terminal width and the terminal thickness of the press-fit portion are reduced to set the press-fit holding force to be lower to prevent such a problem, the press-fit terminal is likely to come off from the through hole, or the contact of the press-fit portion with the inner surface of the through hole becomes unstable, leading to a failure of continuity. Therefore, there has been a problem that it is difficult to optimally set dimensions of the press-fit terminal that achieves both stable holding force and ease of press-fitting.

As one idea to solve such a problem, Patent Literature 1 describes a press-fit terminal provided with a serrated groove on the outer edge of a press-fit portion to increase the holding force when the terminal is press-fitted into a through hole.

Patent Literature 2 describes, in a configuration for electrical connection in which a plurality of leads protruding from an electronic component are inserted into holes for lead connection of a motherboard, a structure in which a hook-shaped protrusion is provided in a spacer that holds the electronic component, the hook-shaped protrusion is inserted into a hole (a hole different from the hole for lead connection) of the motherboard, and a claw portion provided at the distal end of the hook-shaped protrusion is locked to the back surface side of the motherboard.

### CITATION LIST

### Patent Literature

Patent Literature 1: JP 2015-222690 A
Patent Literature 2: JP H09-8182 A
Patent Literature 3: U.S. Pat. No. 11,114,780
Patent Literature 4: U.S. Pat. No. 9,041,196

### SUMMARY OF INVENTION

### Technical Problem

The press-fit terminal of Patent Literature 1 obtains the holding force through press-fitting only from contact between the outer edge of the press-fit portion and the inner surface of the through hole, and thus has limitations on improvement in the holding force even if the serrated groove is provided on the outer edge of the press-fit portion, causing a problem that it is difficult to reliably prevent the terminal from coming off.

The hook-shaped protrusion of Patent Literature 2 prevents the terminal from coming off when the claw portion is locked, but does not stabilize the electronic component or the spacer in a direction other than a direction for preventing the coming-off. In addition, since the hook-shaped protrusion for preventing the coming-off is provided separately from the lead for electrical connection, there are problems such as an increase in the number of components, structure complexity, and an increase in manufacturing cost.

The present invention has been made in view of such a point, and one object of the present invention is to provide a press-fit terminal that can be easily press-fitted into a through hole and be reliably prevented from coming off from the through hole.

### Solution to Problem

A press-fit terminal according to one aspect of the present invention is a press-fit terminal connected to a substrate having a through hole, the press-fit terminal including: a press-fit portion press-fitted and held inside the through hole; and a fitting portion that fits to an outer surface of the substrate outside the through hole and restricts movement of the press-fit terminal in a direction in which the press-fit terminal comes off from the through hole.

### Advantageous Effects of Invention

According to the present invention, it is possible to obtain the press-fit terminal that can be easily press-fitted into the through hole and be reliably prevented from coming off from the through hole.

### BRIEF DESCRIPTION OF DRAWINGS

FIG. 1 is a plan view of a semiconductor device according to the present embodiment.

FIG. 2 is a cross-sectional view taken along line A-A in FIG. 1.

FIG. 3 is a schematic diagram illustrating an example of a circuit configuration of the semiconductor device according to the present embodiment.

FIG. 4 is a view illustrating a state where a press-fit terminal according to a first embodiment has been connected to a substrate.

FIG. 5 is a cross-sectional view taken along line B-B in FIG. 4.

FIG. 6 is a view illustrating the press-fit terminal according to the first embodiment in a front view and a side view.

FIG. 7 is a view illustrating a state where the press-fit terminal according to the first embodiment is being inserted into the through hole of the substrate.

FIG. 8 is a view illustrating a press-fit terminal according to a second embodiment in a front view.

FIG. 9 is a view illustrating a press-fit terminal according to a third embodiment in a front view and a side view.

FIG. 10 is a view illustrating a state where the press-fit terminal according to the third embodiment has been connected to a substrate.

FIG. 11 is a view illustrating a press-fit terminal according to a fourth embodiment in a front view.

FIG. 12 is a view illustrating a press-fit terminal according to a fifth embodiment in a front view and a side view.

FIG. 13 is a view illustrating a press-fit terminal according to a sixth embodiment in a front view and a side view.

### DESCRIPTION OF EMBODIMENTS

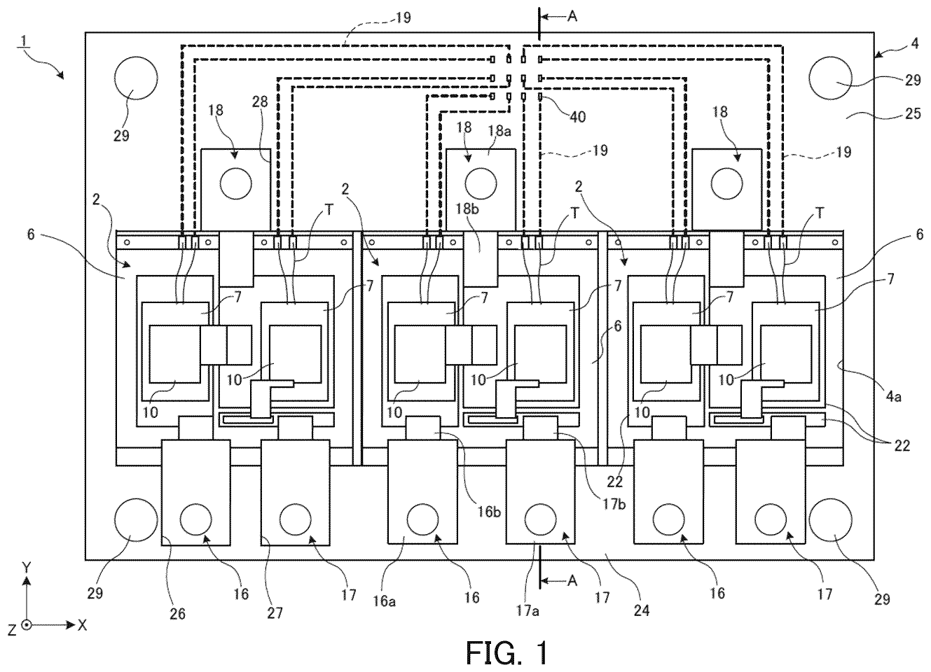

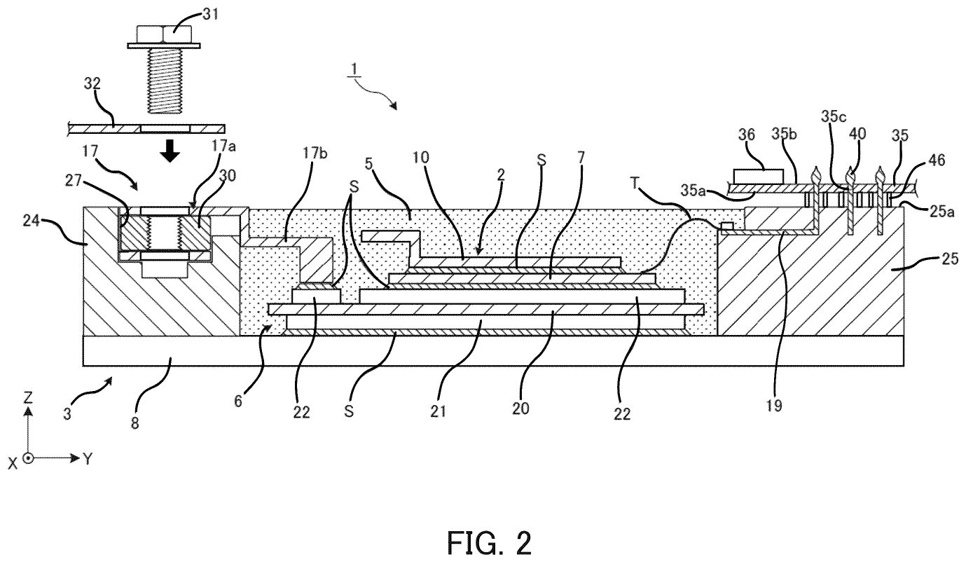

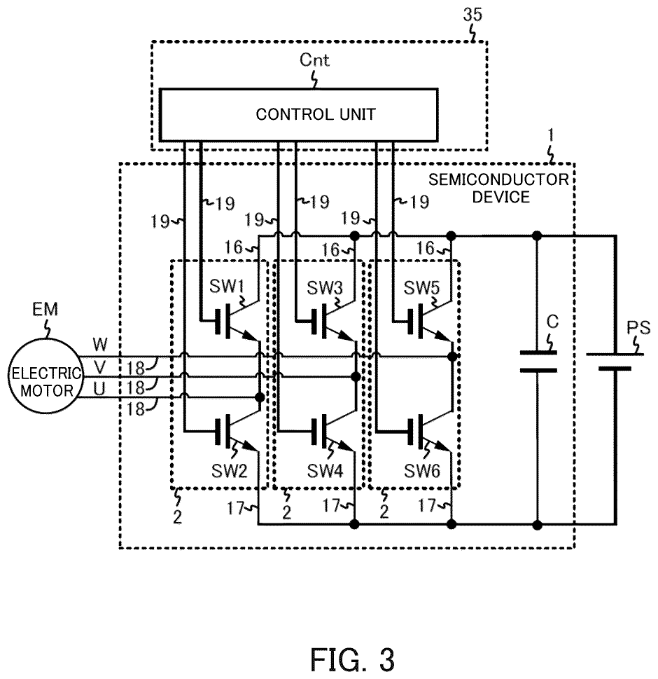

Hereinafter, a semiconductor device to which a press-fit terminal and a terminal structure of the present invention can be applied will be described. FIG. 1 is a plan view of a semiconductor device according to the present embodiment. FIG. 2 is a cross-sectional view taken along line A-A in FIG. 1. FIG. 3 is a schematic diagram illustrating an example of a circuit configuration of the semiconductor device according to the present embodiment. Note that a semiconductor device described below is merely an example, and can be appropriately changed without being limited thereto.

In the following drawings, a longitudinal direction of the semiconductor device is defined as an X direction, a transverse direction of the semiconductor device is defined as a Y direction, and a height direction (a thickness direction of a substrate) is defined as a Z direction. The longitudinal direction of the semiconductor device indicates a direction in which a plurality of semiconductor modules (unit modules) are arrayed. The illustrated X, Y, and Z axes are orthogonal to each other. In some cases, the X direction may be referred to as a left-right direction, the Y direction may be referred to as a front-back direction, and the Z direction may be referred to as a vertical direction. These directions (front-back, left-right, and vertical directions) are terms used for convenience of description, and a correspondence relationship with the XYZ directions may change depending on an attachment orientation of the semiconductor device. The term “in plan view” herein means a case where an upper surface or a lower surface of the semiconductor device is viewed in the Z direction.

The semiconductor device 1 according to the present embodiment is applied to, for example, a power converter such as a power control unit, and is a power semiconductor module constituting an inverter circuit. As illustrated in FIGS. 1 and 2, the semiconductor device 1 includes a plurality of (three in the present embodiment) unit modules 2, a cooler 3 that cools the unit modules 2, a case member 4 that houses the unit modules 2, and sealing resin 5 injected into the case member 4. In FIG. 1, the sealing resin 5 is omitted for the purpose of illustrating the internal structure of the semiconductor device 1.

The unit module 2 includes an insulating substrate 6 and semiconductor elements 7 disposed on the insulating substrate 6. In the present embodiment, three unit modules 2 are arrayed in the X direction. The three unit modules 2 constitute, for example, a U phase, a V phase, and a W phase from the positive side in the X direction, and form a three-phase inverter circuit as a whole. Note that the unit module 2 may be referred to as a power cell or a semiconductor unit.

The cooler 3 includes a base plate 8 formed in a rectangular shape in plan view. The base plate 8 has a rectangular shape in plan view and includes a plate-shaped body having a predetermined thickness. A longitudinal direction of the base plate 8 extends in the left-right direction (X direction) of the semiconductor device 1, and a transverse direction thereof extends in the front-rear direction (Y direction) of the semiconductor device 1. The base plate 8 has one surface (lower surface) and the other surface (upper surface). The one surface forms a heat dissipation surface of the unit module 2. The other surface forms a bonding surface of the unit module 2.

The base plate 8 is made of a material having high heat dissipation (for example, an alloy of aluminum or copper, or the like). In addition, a plating layer having a predetermined thickness is formed on a surface of the base plate 8. The plating layer is preferably made of a plating metal such as nickel. The insulating substrate 6 is disposed on an upper surface of the base plate 8 via a bonding material S such as solder. In addition, a plurality of fins for improving heat dissipation may be provided on a lower surface of the base plate 8.

The insulating substrate 6 is, for example, a direct copper bonding (DCB) substrate, an active metal brazing (AMB) substrate, or a metal base substrate. Specifically, the insulating substrate 6 includes an insulating plate 20, a heat dissipation plate 21 disposed on a lower surface of the insulating plate 20, and a plurality of circuit boards 22 disposed on an upper surface of the insulating plate 20. The insulating substrate 6 is formed in, for example, a rectangular shape in plan view.

For example, the insulating plate 20 is formed of an insulating material, such as a ceramic material such as alumina (Al₂O₃) aluminum nitride (AlN), or silicon nitride (Si₃N₄), a resin material such as epoxy, or an epoxy resin material using a ceramic material as a filler. Note that the insulating plate 20 may be referred to as an insulating layer or an insulating film.

The heat dissipation plate 21 has a predetermined thickness in the Z direction and is formed so as to cover the lower surface of the insulating plate 20. The heat dissipation plate 21 is formed of, for example, a metal plate having good thermal conductivity such as copper or aluminum.

The plurality of circuit boards 22 are formed on the upper surface of the insulating plate 20. The circuit boards 22 are metal layers such as copper foils, and are formed in island shapes in a mutually electrically isolated state on the insulating plate. Note that the circuit board 22 may be referred to as a substrate or a circuit layer.

The semiconductor elements 7 are disposed on an upper surface of the insulating substrate 6 (the circuit board 22) via a bonding material S such as solder. In FIG. 1, two semiconductor elements 7 are illustrated per one insulating substrate 6 for convenience, but more semiconductor elements 7 may be disposed on the insulating substrate 6. The semiconductor elements 7 are formed in a square or rectangular shape in plan view with a semiconductor substrate based on, for example, silicon (Si), silicon carbide (Sic), gallium nitride (GaN), diamond, or the like.

For the semiconductor element 7, a switching element such as an insulated gate bipolar transistor (IGBT) and a power metal oxide semiconductor field effect transistor (power MOSFET), and a diode such as a free wheeling diode (FWD) are used. The switching element and the diode may be connected in anti-parallel. In addition, for the semiconductor element 7, a reverse conducting (RC)-IGBT element of an IGBT and an FWD in unification, a power MOSFET element, or a reverse blocking (RB)-IGBT element highly resistant to a reverse bias may be used.

In addition, the shape, number, arrangement location, and the like of the semiconductor element 7 can appropriately be changed. Note that the semiconductor element 7 of the present embodiment is a vertical switching element in which a functional element such as a transistor is formed on the semiconductor substrate, but is not limited thereto, and may be a horizontal switching element board.

An upper surface electrode of the semiconductor element 7 is conductively connected to a predetermined circuit board 22 via a metal wiring plate 10. The metal wiring plate 10 is formed, for example, by bending a metal material, such as copper material, copper-alloy-based material, aluminum-alloy-based material, or iron-alloy-based material, through pressing or the like. For example, the semiconductor element 7 and one end of the metal wiring plate 10 are bonded to each other with a bonding material S such as solder. In addition, the predetermined circuit board 22 and the other end of the metal wiring plate 10 are bonded to each other with a bonding material S such as solder. The metal wiring plate 10 may be referred to as a lead frame.

The case member 4 is disposed on an outer periphery of the upper surface of the base plate 8. The case member 4 is bonded to the base plate 8 via, for example, an adhesive. The case member 4 has a shape conforming to an outer shape of the base plate 8. More specifically, the case member 4 is formed in a rectangular frame shape having an opening 4a at the center. The three unit modules 2 described above are housed in the opening 4a in the rectangular shape. That is, the three unit modules 2 are housed in a space defined by the frame-shaped case member 4.

The case member 4 is provided with main terminals (a P terminal 16, an N terminal 17, and an M terminal 18) for external connection and a control terminal (a press-fit terminal 40) for control. Regarding walls 24 and 25 paired and opposed in the transverse direction (Y direction) of the case member 4, the wall 24 located on the negative side in the Y direction has recesses 26 and 27 having a rectangular shape in plan view.

A fastening portion 16a of the P terminal 16 is disposed in the recess 26. A single P terminal 16 is disposed per single unit module 2. The P terminal 16 is formed by integrally molding the fastening portion 16a and a plate-shaped portion 16b together. The fastening portion 16a is provided on one end (proximal end) side of the plate-shaped portion 16b. The other end (distal end) of the plate-shaped portion 16b is bonded to the circuit board 22 of the insulating substrate 6 via a bonding material S such as solder.

Similarly, a fastening portion 17a of the N terminal 17 is disposed in the recess 27. A single N terminal 17 is disposed per single unit module 2. The N terminal 17 is formed by integrally molding the fastening portion 17a and a plate-shaped portion 17b together. The fastening portion 17a is provided on one end (proximal end) side of the plate-shaped portion 17b. The other end (distal end) of the plate-shaped portion 17b is bonded to the circuit board 22 of the insulating substrate 6 via a bonding material S such as solder.

Regarding the walls 24 and 25 paired and opposed in the transverse direction (Y direction) of the case member 4, the wall 25 on the positive side in the Y direction has a recess 28 having a rectangular shape in plan view. A fastening portion 18a of the M terminal 18 is disposed in the recess 28. A single M terminal 18 is disposed per single unit module 2. The M terminal 18 is formed by integrally molding the fastening portion 18a and a plate-shaped portion 18b together. The fastening portion 18a is provided on one end (proximal end) side of the plate-shaped portion 18b. The other end (distal end) of the plate-shaped portion 18b is bonded to the circuit board 22 of the insulating substrate 6 via a bonding material S such as solder.

As illustrated in FIG. 2, an outer conductor 32 can be fastened to the fastening portion 17a by screwing a fastening screw 31 to a nut 30 held at the fastening portion 17a. Although the structure of the fastening portion 17a is illustrated in FIG. 2, the fastening portion 16a and the fastening portion 18a are also connected to the external conductor using the same structure.

The P terminal 16, the N terminal 17, and the M terminal 18 constitute a metal wiring plate through which the main current flows. The P terminal 16, the N terminal 17, and the M terminal 18 constitute a main terminal connectable to the external conductor, and one ends of the P terminal 16, the N terminal 17, and the M terminal 18 are bonded to the predetermined circuit board 22 of the insulating substrate 6 via a bonding material S.

These terminals are made of, for example, a metal material, such as a copper material, a copper-alloy-based material, an aluminum-alloy-based material, or an iron-alloy-based material. Note that the shape, arrangement location, the number, and the like of these terminals can be appropriately changed without being limited thereto.

The case member 4 is provided with a plurality of press-fit terminals 40 protruding in the Z direction from an upper surface 25a of the wall 25. In the present embodiment, four press-fit terminals 40 are provided per one unit module 2, and a total of 12 press-fit terminals 40 are arrayed at predetermined intervals in the X direction and the Y direction (see FIG. 1).

Each press-fit terminal 40 is connected to internal wiring 19. The internal wiring 19 is integrally molded (insert-molded) to be embedded in the case member 4. Each internal wiring 19 extends to an outer peripheral portion of the opening 4a, and a wiring member T (bonding wire) is connected to the internal wiring 19. Each internal wiring 19 is connected to the upper surface electrode of the semiconductor element 7 via the wiring member T.

As illustrated in FIG. 2, the plurality of press-fit terminals 40 are connected to a substrate 35 provided outside the semiconductor device 1. The substrate 35 includes a control circuit 36. The connection structure between the press-fit terminal 40 and the substrate 35 will be described later in detail.

The case member 4 has a plurality of penetration holes 29 along its outer peripheral edge. These penetration holes 29 are holes for inserting screws (not illustrated) for fixing the semiconductor device 1. The penetration hole 29 penetrates up to the base plate 8 of the cooler 3.

The resin for the case member 4 can be selected from PPS, polybutylene terephthalate (PBT), polybutyl acrylate (PBA), polyamide (PA), acrylonitrile butadiene styrene (ABS), liquid crystal polymer (LCP), polyether ether ketone (PEEK), polybutylene succinate (PBS), and insulating resins such as urethane and silicon. The selected resin may be a mixture of two or more kinds of resins. The resin may contain a filler (for example, a glass filler) for improving strength and/or functionality.

In addition, an internal space defined by the frame-shaped case member 4 is filled with the sealing resin 5. The insulating substrate 6 and the semiconductor element 7 mounted on the insulating substrate 6 are sealed in the space by the sealing resin 5. The case member 4 defines a space for housing the plurality of unit modules 2 (the insulating substrate 6 and the semiconductor element 7) and the sealing resin 5.

The sealing resin 5 is made of a thermosetting resin. The sealing resin 5 preferably contains at least one of epoxy, silicone, urethane, polyimide, polyamide, and polyamide-imide. For example, an epoxy resin mixed with a filler is suitable for the sealing resin 5 from the viewpoint of insulation, heat resistance, and heat dissipation.

FIG. 3 is an example of a circuit configuration illustrating an application example of the semiconductor device 1. In FIG. 3, the same components as those illustrated in FIGS. 1 and 2 are denoted by the same reference numerals, and the description thereof will be omitted. The semiconductor device 1 illustrated in FIG. 3 is applied as an inverter that converts DC power supplied from a power supply PS into AC power to drive an electric motor EM.

That is, the three unit modules 2 illustrated in FIG. 3 include switches SW1 to SW6 as the plurality of semiconductor elements 7. The switches SW1 to SW6 are, for example, insulated gate bipolar transistors (IGBTs). A collector terminal of each of the switches SW1, SW3, and SW5 is connected to a positive terminal of the power supply PS via one terminal of a capacitor C, and an emitter terminal of each of the switches SW2, SW4, and SW6 is connected to a negative terminal of the power supply PS via the other terminal of the capacitor C. A connection point between an emitter terminal of the switch SW1 and a collector terminal of the switch SW2 is connected to a U-phase input terminal of the electric motor EM, a connection point between an emitter terminal of the switch SW3 and a collector terminal of the switch SW4 is connected to a V-phase input terminal of the electric motor EM, and a connection point between an emitter terminal of the switch SW5 and a collector terminal of the switch SW6 is connected to a W-phase input terminal of the electric motor EM. A gate terminal of the switch SW1, a gate terminal of the switch SW2, a gate terminal of the switch SW3, a gate terminal of the switch SW4, a gate terminal of the switch SW5, and a gate terminal of the switch SW6 are connected to a control unit Cnt provided outside the semiconductor device 1. The control unit Cnt is included in the control circuit 36 (FIG. 2) of the substrate 35.

In each of the switches SW1 to SW6, the diode may be connected in anti-parallel (here, “connected in anti-parallel”means that an anode of the diode is connected to the emitter of the switch and a cathode of the diode is connected to the collector of the switch). In addition, the switches SW1 to SW6 may be made of the metal oxide semiconductor field effect transistor (MOSFET) or the like.

The capacitor C smooths a voltage output from the power supply PS to the unit module 2.

The control unit Cnt turns on or off each of the switches SW1 to SW6. When each of the switches SW1 to SW6 is turned on or off, the DC voltage output from the power supply PS is converted into three AC voltages having phases different from each other by 120 degrees, and when the AC voltages are applied to the U-phase input terminal, the V-phase input terminal, and the W-phase input terminal of the electric motor EM, the electric motor EM is driven.

The substrate 35 has a lower surface 35a facing the semiconductor device 1 and an upper surface 35b facing an opposite side of the lower surface 35a, and has a plurality of through holes 35c penetrating from the lower surface 35a to the upper surface 35b. The semiconductor device 1 is conductively connected to the substrate 35 via the press-fit terminals 40 when the plurality of press-fit terminals 40 are inserted into the plurality of through holes 35c.

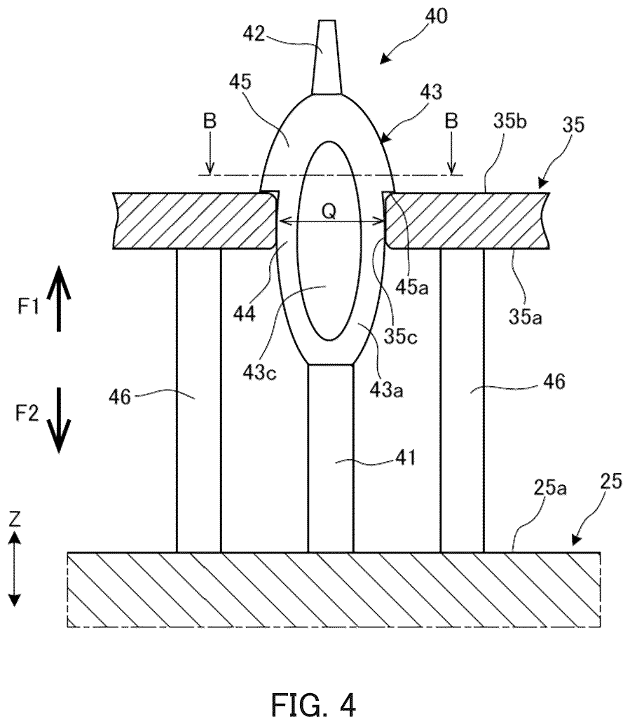

The through hole 35c is a substantially circular hole in plan view. A contact portion is formed on an inner surface (inner peripheral surface) of the through hole 35c by a plating layer or the like. In the following description, the radial dimension of the through hole 35c is referred to as a hole diameter Q (see FIG. 4).

The press-fit terminal 40 is made of a conductive metal material. A copper material is suitable for a base material of the press-fit terminal 40 from the viewpoint of workability during manufacturing and conductivity, and in particular, phosphor bronze having excellent spring property and high strength is suitable. The press-fit terminal 40 is manufactured by pressing or performing other processing on such a metal material. In addition, the surface of the press-fit terminal 40 may be plated with nickel, tin, or the like to prevent corrosion of the press-fit terminal 40.

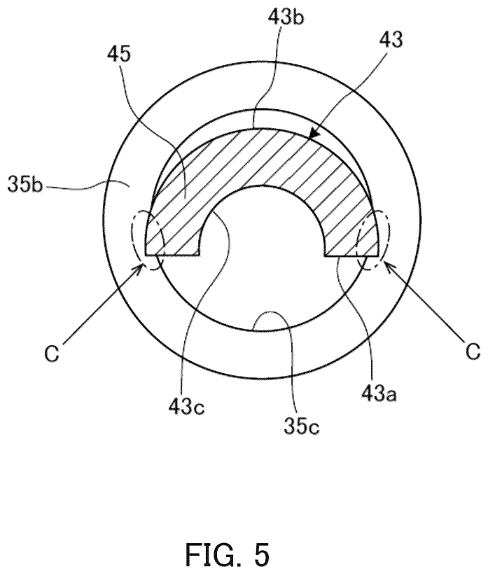

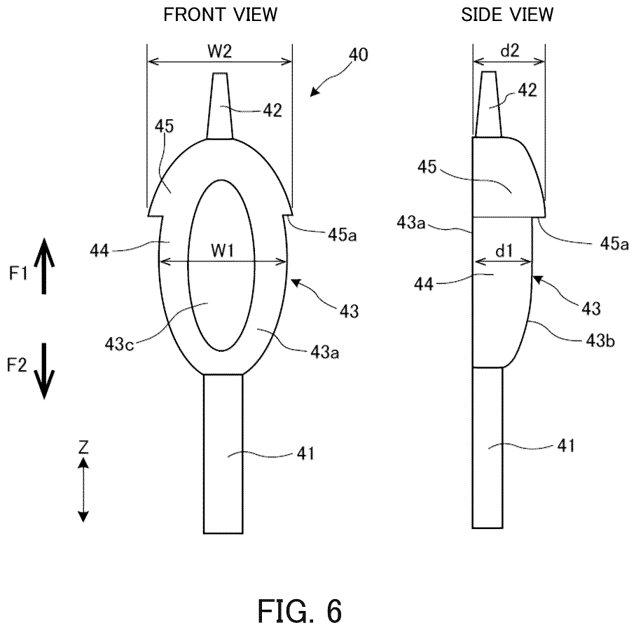

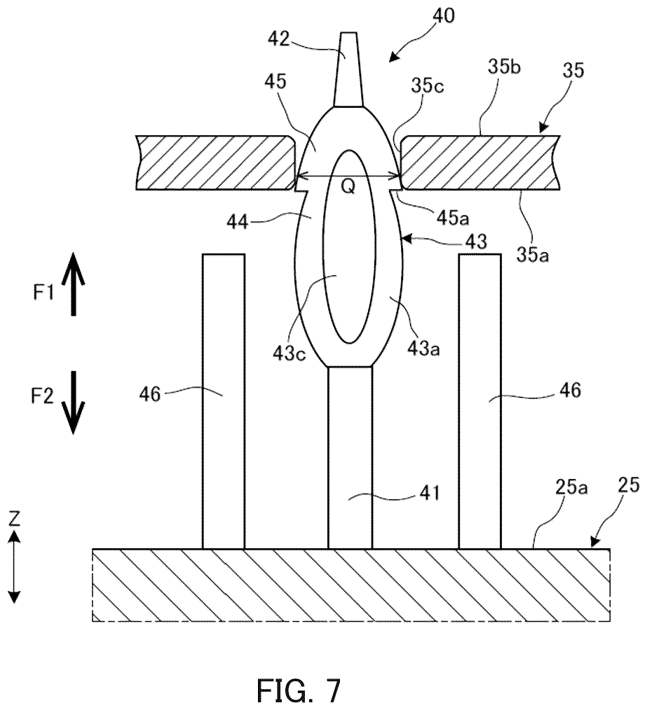

A detailed configuration of the press-fit terminal 40 of a first embodiment will be described with reference to FIGS. 4 to 7. FIGS. 4 and 5 illustrate a state where the press-fit terminal 40 has been connected to the substrate 35. FIG. 6 illustrates the press-fit terminal 40 in an initial state before being connected to the substrate 35. FIG. 7 illustrates a state where the press-fit terminal 40 is being inserted into the through hole 35c of the substrate 35. An arrow F1 illustrated in the drawing is a direction (insertion direction) in which the press-fit terminal 40 is inserted into the through hole 35c when the press-fit terminal 40 is connected to the substrate 35. An arrow F2 is a direction (detachment direction) in which the press-fit terminal 40 comes off from the through hole 35c in a state where the press-fit terminal 40 is connected to the substrate 35.

The press-fit terminal 40 includes a base portion 41 connected to the wall 25 of the case member 4, a guide portion 42 provided at a distal end, and a connecting portion 43 provided between the base portion 41 and the guide portion 42.

As illustrated in FIG. 4, the base portion 41 protrudes in a rod shape with a predetermined length in the Z direction from the upper surface 25a of the wall 25. The base portion 41 has a prismatic shape or a cylindrical shape.

The guide portion 42 has a shape that gradually narrows from the proximal end portion connected to the connecting portion 43 toward the distal end portion. The width of the guide portion 42 is smaller than the hole diameter Q of the through hole 35c. The guide portion 42 facilitates the insertion of the connecting portion 43 into the through hole 35c when the press-fit terminal 40 is connected to the substrate 35. In a state where the connecting portion 43 is connected to the substrate 35, the guide portion 42 protrudes to the outside (upper side) of the substrate 35 after passing through the through hole 35c (see FIG. 4).

The connecting portion 43 is a portion that is press-fitted into the through hole 35c of the substrate 35 and fits to the upper surface 35b that is an outer surface of the substrate 35 outside the substrate 35. In both a front view and a side view illustrated in FIG. 6, the connecting portion 43 has a larger dimension than the base portion 41. In the following description, a lateral width of the connecting portion 43 in the front view of the press-fit terminal 40 is referred to as a terminal width. In addition, a lateral width of the connecting portion 43 in the side view of the press-fit terminal 40 is referred to as a terminal thickness. Both the terminal width and the terminal thickness indicate the size of the connecting portion 43 in the radial direction (direction perpendicular to the Z direction) of the through hole 35c.

The connecting portion 43 has a flat surface 43a on the front side, a curved surface 43b on the back side of the flat surface 43a, and a recess 43c at the central portion of the flat surface 43a. The recess 43c has a shape recessed from the flat surface 43a. As illustrated in FIG. 5, when the connecting portion 43 is viewed in a cross section perpendicular to the Z direction, the curved surface 43b has a semicircular convex shape, and the recess 43c has a semicircular concave shape.

The connecting portion 43 includes a press-fit portion 44 and a fitting portion 45. The press-fit portion 44 is disposed on the proximal end side of the connecting portion 43 connected to the base portion 41, and the fitting portion 45 is disposed on the distal end side of the connecting portion 43 connected to the guide portion 42. Therefore, when the press-fit terminal 40 is inserted into the through hole 35c, the fitting portion 45 first passes through the through hole 35c, and then the press-fit portion 44 enters the through hole 35c.

As illustrated in FIG. 6, the terminal width and the terminal thickness of the press-fit portion 44 gradually increase from the proximal end side connected to the base portion 41 toward the distal end direction of the press-fit terminal 40, and the terminal width and the terminal thickness become maximum near the center of the length of the connecting portion 43 in the Z direction. The maximum terminal width of the press-fit portion 44 is defined as a maximum terminal width W1, and the maximum terminal thickness of the press-fit portion 44 is defined as a maximum terminal thickness d1. The terminal width and the terminal thickness of the press-fit portion 44 gradually decrease from the position of the maximum terminal width W1 and the maximum terminal thickness d1 toward the distal end direction of the press-fit terminal 40. That is, the press-fit portion 44 has a shape similar to a part of an elliptical shape whose major axis is oriented in the Z direction in the front view.

As illustrated in FIG. 6, the terminal width and the terminal thickness of the fitting portion 45 gradually increase from the distal end side connected to the guide portion 42 toward the proximal end direction of the press-fit terminal 40, and the terminal width and the terminal thickness become maximum at the position of a fitting surface 45a forming a boundary portion with the press-fit portion 44. The maximum terminal width of the fitting portion 45 is defined as a maximum terminal width W2, and the maximum terminal thickness of the fitting portion 45 is defined as a maximum terminal thickness d2. The fitting portion 45 has a shape similar to a part of an elliptical shape whose major axis is oriented in the Z direction in the front view.

A relationship between the maximum terminal width W2 of the fitting portion 45 and the maximum terminal width W1 of the press-fit portion 44 is W2>W1. In addition, a relationship between the maximum terminal thickness d2 of the fitting portion 45 and the maximum terminal thickness d1 of the press-fit portion 44 is d2>d1. That is, the size (terminal width and terminal thickness) of the fitting portion 45 in the radial direction of the through hole 35c is larger than the size (terminal width and terminal thickness) of the press-fit portion 44, and the fitting portion 45 has the step-shaped fitting surface 45a between the fitting portion 45 and the press-fit portion 44.

In an initial state (FIG. 6) before the press-fit terminal 40 is inserted into the through hole 35c, both the maximum terminal width W1 of the press-fit portion 44 and the maximum terminal width W2 of the fitting portion 45 are larger than the hole diameter Q (FIG. 4) of the through hole 35c. As illustrated in FIG. 7, in the process of inserting the press-fit terminal 40 into the through hole 35c in the insertion direction F1, when an outer surface (curved surface 43b) of the connecting portion 43 comes into contact with the inner surface of the through hole 35c, the connecting portion 43 is pushed inward and elastically deformed so as to reduce the terminal width. Since the thickness of the connecting portion 43 is reduced (thinned) at the recess 43c, the connecting portion 43 can be smoothly elastically deformed.

FIG. 7 illustrates a stage in which the fitting portion 45 is passing through the inside of the through hole 35c. In this stage, an outer surface of the fitting portion 45 comes into contact with the inner surface of the through hole 35c and is deformed to be pushed inward, and the terminal width of the fitting portion 45 temporarily becomes equal to or smaller than the hole diameter Q of the through hole 35c.

When the press-fit terminal 40 is inserted deeper in an insertion direction F1 than the position in FIG. 7, as illustrated in FIG. 4, the fitting portion 45 passes through the through hole 35c and comes out of the substrate 35, and the press-fit portion 44 enters the through hole 35c. The fitting portion 45 that has passed through the through hole 35c is released from the pushing received from the inner surface of the through hole 35c, and is restored from the elastic deformation to widen the terminal width.

In the state of FIG. 4, an outer surface of the press-fit portion 44 comes into contact with the inner surface of the through hole 35c and is deformed to be pushed inward, and the terminal width becomes smaller than that in the initial state illustrated in FIG. 6. The deformed outer surface of the press-fit portion 44 is pushed against the inner surface of the through hole 35c to generate a holding force. As a result, the press-fit portion 44 is press-fitted into the through hole 35c. In the press-fit portion 44, a portion having the maximum terminal width W1 in the initial state is in contact with the inner surface of the through hole 35c, and the press-fit portion 44 is stably held at the substrate 35. In addition, the outer surface of the press-fit portion 44 is in contact with the contact portion of the inner surface of the through hole 35c, and the press-fit terminal 40 and the contact portion of the through hole 35c are conductively connected.

In the state where connection between the press-fit terminal 40 and the substrate 35 is completed as illustrated in FIG. 4, the fitting surface 45a of the fitting portion 45 located outside the substrate 35 faces the upper surface 35b of the substrate 35. When the fitting surface 45a is in contact with the upper surface 35b, the movement of the press-fit terminal 40 with respect to the substrate 35 in the detachment direction F2 is restricted. That is, after passing through the through hole 35c, the fitting portion 45 fits to the upper surface 35b that is the outer surface of the substrate 35 outside the substrate 35. In a plan view viewed along the Z direction, a region C illustrated in FIG. 5 is a fitting portion between the fitting surface 45a of the fitting portion 45 and the upper surface 35b of the substrate 35.

As described above, the connecting portion 43 of the press-fit terminal 40 is connected to the substrate 35 by using the press-fit portion 44 that is press-fitted and held inside the through hole 35c and the fitting portion 45 that fits to the outer surface (upper surface 35b) of the substrate 35 outside the through hole 35c and restricts the movement of the press-fit terminal 40 in the direction in which the press-fit terminal 40 comes off from the through hole 35c. Through the press-fitting of the press-fit portion 44, the adhesion level to the through hole 35c can be increased to achieve reliable electrical contact between the contact portion on the substrate 35 side and the press-fit terminal 40. In addition, through the fitting of the fitting portion 45, it is possible to reliably restrict the position change of the press-fit terminal 40 in the Z direction with respect to the substrate 35, particularly, the movement of the press-fit terminal 40 in the detachment direction F2 (coming-off of the press-fit terminal 40 from the through hole 35c).

Unlike the press-fit terminal 40 of the present embodiment, a press-fit terminal of a type that performs connection only through press-fitting into the through hole has the following problem. When the terminal width and the terminal thickness are increased for the purpose of increasing the press-fit holding force, the resistance during press-fitting into the through hole becomes excessive, making it likely that the press-fit terminal will be broken or bent. Conversely, when the terminal width and the terminal thickness are reduced, the press-fit terminal easily comes off after being press-fitted into the through hole, or the contact between the contact portion of the through hole and the press-fit terminal becomes poor. Therefore, it is very difficult to adjust the terminal width and the terminal thickness of the press-fit terminal to obtain the optimum holding force.

On the other hand, in the press-fit terminal 40 of the present embodiment, the connecting portion 43 includes the press-fit portion 44 and the fitting portion 45, the press-fit portion 44 plays a role in performing press-fitting into the through hole 35c and electrical connection with the substrate 35, and the fitting portion 45 plays a role in preventing the press-fit terminal 40 from coming off from the through hole 35c. Since the press-fit portion 44 and the fitting portion 45 play separate roles, it is possible to perform shape setting and adjustment focused on each role, and it is possible to easily improve the connectivity between the press-fit terminal 40 and the substrate 35. For example, since the press-fit terminal 40 is prevented from coming off by the fitting portion 45, it is not necessary to excessively increase the terminal width and the terminal thickness of the press-fit portion 44 for the purpose of preventing the press-fit terminal 40 from coming off, and thus it is possible to suppress a press-fit load when the press-fit portion 44 is inserted into the through hole 35c.

Note that, although the fitting portion 45 having a terminal width and a terminal thickness larger than those of the press-fit portion 44 passes through the through hole 35c when the press-fit terminal 40 is connected to the substrate 35, since a ratio of the fitting portion 45 to the entire connecting portion 43 is small, an increase in the press-fit load by the fitting portion 45 is limited. Therefore, the press-fit terminal 40 including the fitting portion 45 can achieve the ease of insertion into the through hole 35c.

As illustrated in FIG. 4, the wall 25 of the case member 4 is further provided with a support portion 46 in the vicinity of the press-fit terminal 40. The support portion 46 is a rod-like or columnar protrusion protruding in the Z direction from the upper surface 25a of the wall 25. In a state where the press-fit terminal 40 is connected to the substrate 35, a distal end of the support portion 46 faces the lower surface 35a of the substrate 35. The lower surface 35a of the substrate 35 is a second outer surface located on an opposite side of one outer surface (upper surface 35b) the fitting surface 45a of the fitting portion 45 faces.

When the distal end of the support portion 46 is in contact with the lower surface 35a of the substrate 35, the movement of the press-fit terminal 40 with respect to the substrate 35 in the insertion direction F1 is restricted. That is, the maximum insertion amount of the press-fit terminal 40 into the through hole 35c is determined by providing the support portion 46. The protrusion amount of the support portion 46 from the upper surface 25a of the wall 25 is set such that the fitting surface 45a of the fitting portion 45 faces the upper surface 35b of the substrate 35 with a predetermined clearance. As described above, since the movement of the press-fit terminal 40 with respect to the substrate 35 in the detachment direction F2 is restricted by providing the fitting between the fitting portion 45 and the substrate 35, a stable insertion position of the press-fit terminal 40 can be easily set in both the insertion direction F1 and the detachment direction F2 according to the structure illustrated in FIG. 4.

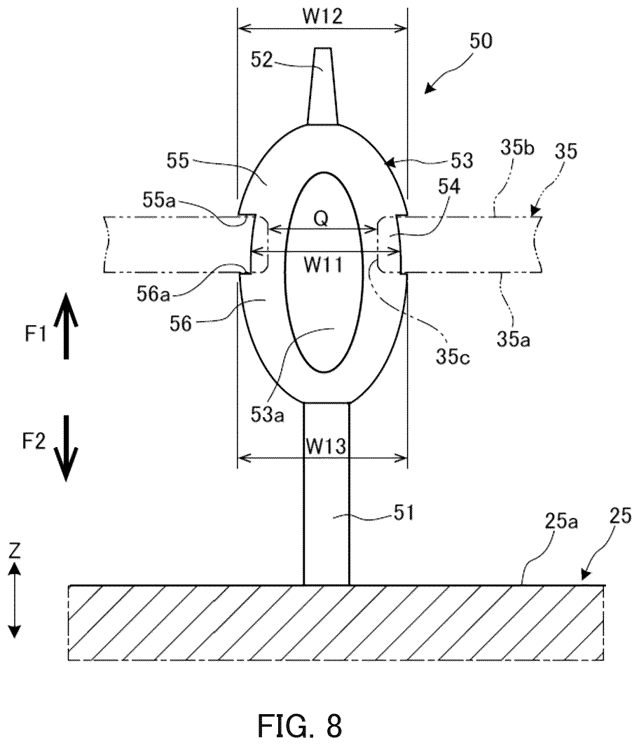

Next, modifications of the press-fit terminal will be described with reference to FIGS. 8 to 13.

FIG. 8 illustrates a press-fit terminal 50 of a second embodiment. In FIG. 8, the press-fit terminal 50 in an initial state before being connected to the substrate 35 is illustrated, and the substrate 35 and the through hole 35c are virtually illustrated by a two-dot chain line. A base portion 51 and a guide portion 52 of the press-fit terminal 50 have the same configuration and role as those of the base portion 41 and the guide portion 42 of the press-fit terminal 40 of the first embodiment, and a detailed description thereof will be omitted.

A connecting portion 53 of the press-fit terminal 50 includes a press-fit portion 54, a fitting portion 55, and a second fitting portion 56. The fitting portion 55 is disposed on the distal end side of the connecting portion 53 connected to the guide portion 52. The second fitting portion 56 is disposed on the proximal end side of the connecting portion 53 connected to the base portion 51. The press-fit portion 54 is disposed in a region between the fitting portion 55 and the second fitting portion 56.

The connecting portion 53 has a recess 53a. Similarly to the recess 43c of the press-fit terminal 40 of the first embodiment, the recess 53a is provided as a thinning shape for facilitating deformation of the connecting portion 53.

The press-fit portion 54 and the fitting portion 55 correspond to the press-fit portion 44 and the fitting portion 45 of the press-fit terminal 40 of the first embodiment. The press-fit portion 54 has a maximum terminal width W11 larger than the hole diameter Q of the through hole 35c in the initial state, and is press-fitted into the through hole 35c in a deformed state where the terminal width becomes equal to or less than the hole diameter Q.

The fitting portion 55 has a maximum terminal width W12 larger than the maximum terminal width W11 of the press-fit portion 54 in the initial state. In a state where the fitting portion 55 passes through the through hole 35c and comes out of the substrate 35, a fitting surface 55a (step shape of a boundary portion with the press-fit portion 54) faces and fits to the upper surface 35b of the substrate 35. As a result, the movement of the press-fit terminal 50 with respect to the substrate 35 in the detachment direction F2 is restricted.

The terminal width (and the terminal thickness) of the second fitting portion 56 gradually increases from the proximal end side connected to the base portion 51 toward the distal end direction of the press-fit terminal 50, and the terminal width (and the terminal thickness) becomes maximum at the position of a second fitting surface 56a that is a step shape of a boundary portion with the press-fit portion 54. The maximum terminal width of the second fitting portion 56 is defined as a maximum terminal width W13. The maximum terminal width W13 is larger than the hole diameter Q of the through hole 35c.

In a state where the press-fit portion 54 is press-fitted into the through hole 35c, the second fitting portion 56 is located outside the substrate 35, and the second fitting surface 56a faces the lower surface 35a of the substrate 35. When the second fitting surface 56a is in contact with the lower surface 35a, the movement of the press-fit terminal 50 with respect to the substrate 35 in the insertion direction F1 is restricted. That is, the maximum insertion amount of the press-fit terminal 50 into the through hole 35c is determined by providing the fitting between the second fitting portion 56 and the substrate 35.

Therefore, in the press-fit terminal 50 including the press-fit portion 54, the fitting portion 55, and the second fitting portion 56, a stable insertion position of the press-fit terminal 50 can be easily set in both the insertion direction F1 and the detachment direction F2. Since the movement of the press-fit terminal 50 in the insertion direction F1 is restricted by the second fitting portion 56, a structure without the support portion 46 illustrated in FIG. 4 can be adopted.

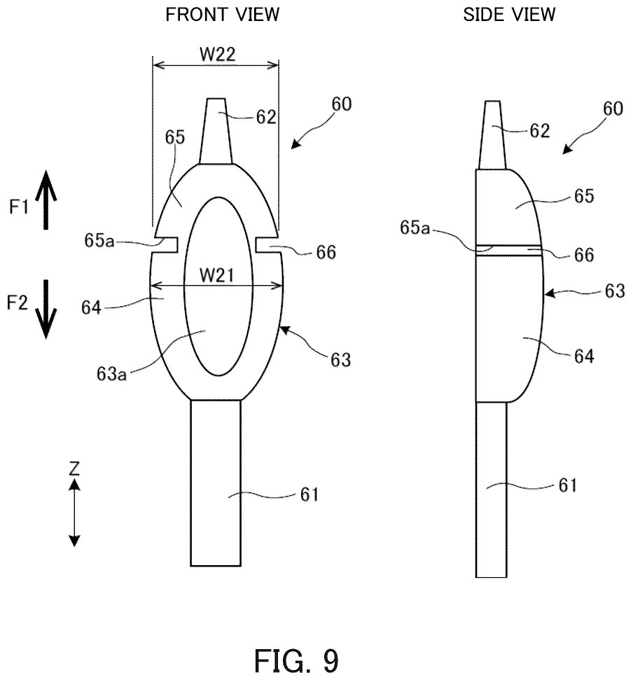

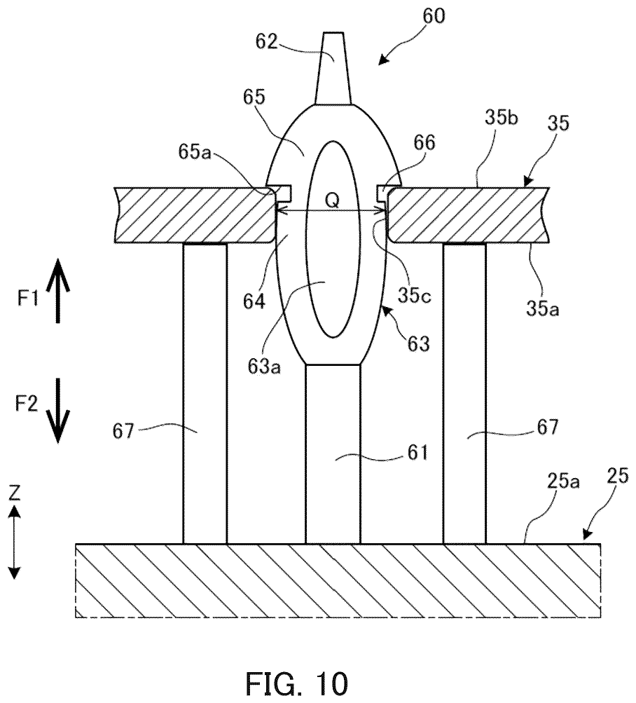

FIGS. 9 and 10 illustrate a press-fit terminal 60 of a third embodiment. FIG. 9 illustrates the press-fit terminal 60 in an initial state before being connected to the substrate 35. FIG. 10 illustrates a state where the press-fit terminal 60 has been connected to the substrate 35. A base portion 61 and a guide portion 62 of the press-fit terminal 60 have the same configuration and role as those of the base portion 41 and the guide portion 42 of the press-fit terminal 40 of the first embodiment, and a detailed description thereof will be omitted.

A connecting portion 63 of the press-fit terminal 60 has a press-fit portion 64 and a fitting portion 65. The press-fit portion 64 is disposed on the proximal end side of the connecting portion 63 connected to the base portion 61. The fitting portion 65 is disposed on the distal end side of the connecting portion 63 connected to the guide portion 62.

The press-fit portion 64 and the fitting portion 65 are separated by a groove 66. The connecting portion 63 in a front view has a shape similar to an elliptical shape whose major axis is oriented in the Z direction, and a groove 66 is formed in such a manner that a part of the elliptical shape is cut out. The fitting portion 65 has a fitting surface 65a forming an inner surface of the groove 66.

The connecting portion 63 has a recess 63a. Similarly to the recess 43c of the press-fit terminal 40 of the first embodiment, the recess 63a is provided as a thinning shape for facilitating deformation of the connecting portion 63. The groove 66 is formed from an outer surface of the connecting portion 63 to a predetermined depth (a depth not reaching the recess 63a).

The press-fit portion 64 has a maximum terminal width W21 larger than the hole diameter Q of the through hole 35c in the initial state (see FIG. 9). Then, when the press-fit terminal 60 is connected to the substrate 35, the press-fit portion 64 is press-fitted into the through hole 35c in a deformed state where the terminal width becomes equal to or less than the hole diameter Q (see FIG. 10).

The support portion 67 illustrated in FIG. 10 has the same role as the support portion 46 illustrated in FIG. 4. The support portion 67 is provided so as to protrude from the upper surface 25a of the wall 25, and, when the distal end of the support portion 67 is in contact with the lower surface 35a of the substrate 35, the movement of the press-fit terminal 60 with respect to the substrate 35 in the insertion direction F1 is restricted.

The fitting portion 65 has a maximum terminal width W22 larger than the hole diameter Q of the through hole 35c in the initial state (see FIG. 9). Then, in a state where the press-fit terminal 60 is connected to the substrate 35, the fitting portion 65 fits to the substrate 35 with the fitting surface 65a facing the upper surface 35b of the substrate 35 (see FIG. 10). As a result, the movement of the press-fit terminal 60 with respect to the substrate 35 in the detachment direction F2 is restricted.

That is, the press-fit portion 64 and the fitting portion 65 of the press-fit terminal 60 have the same functions as those of the press-fit portion 44 and the fitting portion 45 of the press-fit terminal 40 of the first embodiment. In the press-fit terminal 40, the step shape is provided between the press-fit portion 44 and the fitting portion 45 in the initial state, so that the fitting surface 45a is present in advance on the outer surface of the connecting portion 43. On the other hand, in the press-fit terminal 60, the groove 66 is provided between the press-fit portion 64 and the fitting portion 65 in the initial state, so that the fitting surface 65a appears on an outer surface of the connecting portion 63 due to a difference in the deformation amount between the press-fit portion 64 and the fitting portion 65 when the press-fit portion 64 is press-fitted into the through hole 35c.

As a difference from the press-fit terminal 40 of the first embodiment, in the press-fit terminal 60, the maximum terminal width W21 of the press-fit portion 64 in the initial state is larger than the maximum terminal width W22 of the fitting portion 65. Then, when the press-fit portion 64 is press-fitted into the through hole 35c, the terminal width of the press-fit portion 64 becomes smaller than the terminal width of the fitting portion 65.

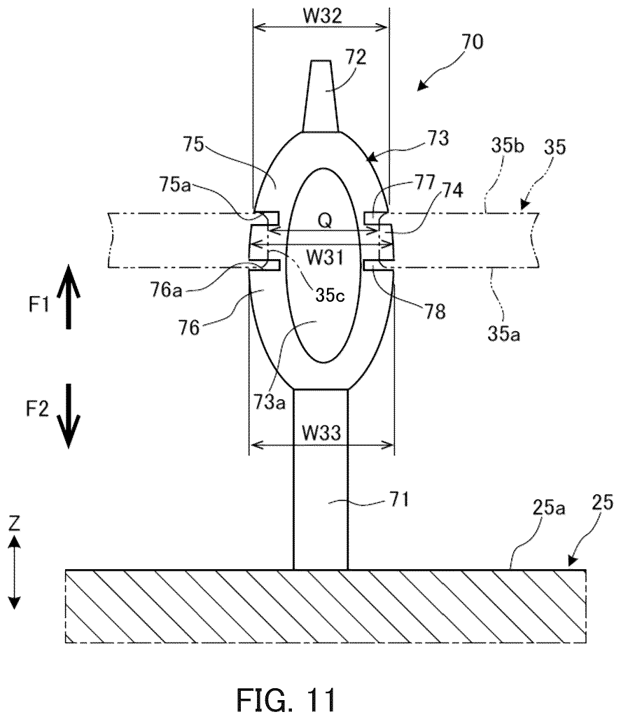

FIG. 11 illustrates a press-fit terminal 70 of a fourth embodiment. In FIG. 11, the press-fit terminal 70 in an initial state before being connected to the substrate 35 is illustrated, and the substrate 35 and the through hole 35c are virtually illustrated by a two-dot chain line. A base portion 71 and a guide portion 72 of the press-fit terminal 70 have the same configuration and role as those of the base portion 41 and the guide portion 42 of the press-fit terminal 40 of the first embodiment, and a detailed description thereof will be omitted.

A connecting portion 73 of the press-fit terminal 70 includes a press-fit portion 74, a fitting portion 75, and a second fitting portion 76. The fitting portion 75 is disposed on the distal end side of the connecting portion 73 connected to the guide portion 72. The second fitting portion 76 is disposed on the proximal end side of the connecting portion 73 connected to the base portion 71. The press-fit portion 74 is disposed in a region between the fitting portion 75 and the second fitting portion 76.

The press-fit portion 74 and the fitting portion 75 are separated by a groove 77. The press-fit portion 74 and the second fitting portion 76 are separated by a groove 78. The connecting portion 73 has a recess 73a. Similarly to the recess 43c of the press-fit terminal 40 of the first embodiment, the recess 73a is provided as a thinning shape for facilitating deformation of the connecting portion 73. The groove 77 and the groove 78 are formed from an outer surface of the connecting portion 73 to a predetermined depth (a depth not reaching the recess 73a).

The press-fit portion 74 and the fitting portion 75 correspond to the press-fit portion 64 and the fitting portion 65 of the press-fit terminal 60 of the third embodiment. The press-fit portion 74 has a maximum terminal width W31 larger than the hole diameter Q of the through hole 35c in the initial state, and is press-fitted into the through hole 35c in a deformed state where the terminal width becomes equal to or less than the hole diameter Q.

The fitting portion 75 has a maximum terminal width W32 larger than the hole diameter Q of the through hole 35c of the press-fit portion 74 in the initial state. In a state where the fitting portion 75 passes through the through hole 35c and comes out of the substrate 35, a fitting surface 75a (inner surface of the groove 77) faces and fits to the upper surface 35b of the substrate 35. As a result, the movement of the press-fit terminal 70 with respect to the substrate 35 in the detachment direction F2 is restricted.

The terminal width (and the terminal thickness) of the second fitting portion 76 gradually increases from the proximal end side connected to the base portion 71 toward the distal end direction of the press-fit terminal 70, and the terminal width (and the terminal thickness) becomes maximum at the position of a second fitting surface 76a constituting an inner surface of the groove 78. The maximum terminal width of the second fitting portion 76 is defined as a maximum terminal width W33. The maximum terminal width W33 is larger than the hole diameter Q of the through hole 35c.

In a state where the press-fit portion 74 is press-fitted into the through hole 35c, the second fitting portion 76 is located outside the substrate 35, and the second fitting surface 76a faces the lower surface 35a of the substrate 35. When the second fitting surface 76a is in contact with the lower surface 35a, the movement of the press-fit terminal 70 with respect to the substrate 35 in the insertion direction F1 is restricted. That is, the maximum insertion amount of the press-fit terminal 70 into the through hole 35c is determined by providing the fitting between the second fitting portion 76 and the substrate 35.

Therefore, in the press-fit terminal 70 including the press-fit portion 74, the fitting portion 75, and the second fitting portion 76, a stable insertion position of the press-fit terminal 70 can be easily set in both the insertion direction F1 and the detachment direction F2. Since the movement of the press-fit terminal 70 in the insertion direction F1 is restricted by the second fitting portion 76, a structure without the support portion 46 illustrated in FIG. 4 or the support portion 67 illustrated in FIG. 10 can be adopted.

As described above, the press-fit portion 74, the fitting portion 75, and the second fitting portion 76 of the press-fit terminal 70 have the same functions as those of the press-fit portion 54, the fitting portion 55, and the second fitting portion 56 of the press-fit terminal 50 (FIG. 8) of the second embodiment. In the press-fit terminal 50, the step shape is provided between the press-fit portion 54 and the fitting portion 55 and between the press-fit portion 54 and the second fitting portion 56 in the initial state, so that the fitting surface 55a and the second fitting surface 56a are present in advance on an outer surface of the connecting portion 53. On the other hand, in the press-fit terminal 70, the groove 77 is provided between the press-fit portion 74 and the fitting portion 75 and the groove 78 is provided between the press-fit portion 74 and the second fitting portion 76 in the initial state, so that the fitting surface 75a and the second fitting surface 76a appear on the outer surface of the connecting portion 73 due to a difference in the deformation amount between the press-fit portion 74, the fitting portion 75, and the second fitting portion 76 when the press-fit portion 74 is press-fitted into the through hole 35c.

In the press-fit terminal 50 of the second embodiment (FIG. 8), the fitting portion 55 and the second fitting portion 56 each have the step between the fitting portion 55 or the second fitting portion 56 and the press-fit portion 54 in the initial state, and in the press-fit terminal 70 of the fourth embodiment (FIG. 11), the fitting portion 75 and the second fitting portion 76 each have the groove 77 and 78 between the fitting portion 75 or the second fitting portion 76 and the press-fit portion 74 in the initial state; however, one of the fitting portion and the second fitting portion may be configured using a step shape, and the other of the fitting portion and the second fitting portion may be configured using a groove.

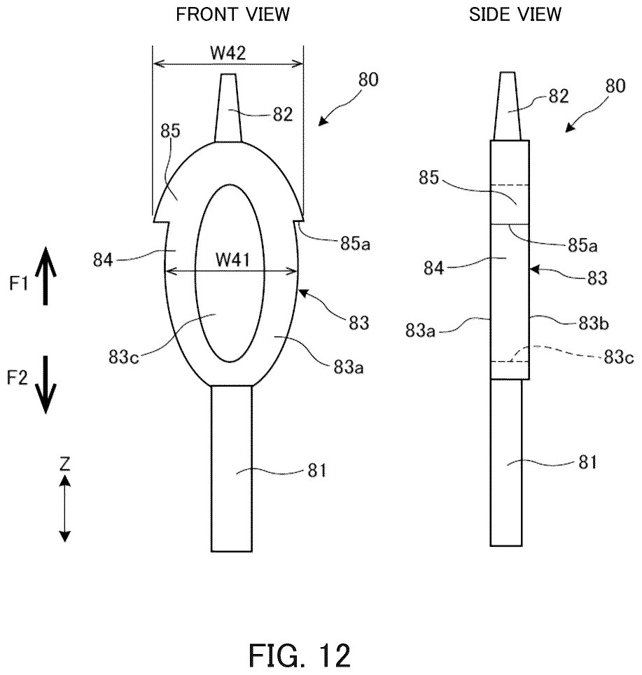

FIG. 12 illustrates a press-fit terminal 80 of a fifth embodiment. FIG. 12 illustrates the press-fit terminal 80 in an initial state before being connected to the substrate 35. A base portion 81 and a guide portion 82 of the press-fit terminal 80 have the same configuration and role as those of the base portion 41 and the guide portion 42 of the press-fit terminal 40 of the first embodiment, and a detailed description thereof will be omitted.

A connecting portion 83 of the press-fit terminal 80 has a press-fit portion 84 and a fitting portion 85. The press-fit portion 84 is disposed on the proximal end side of the connecting portion 83 connected to the base portion 81. The fitting portion 85 is disposed on the distal end side of the connecting portion 83 connected to the guide portion 82.

The shape of the connecting portion 83 in a front view is substantially the same as the shape of the connecting portion 43 in the press-fit terminal 40 of the first embodiment (see FIG. 6), and a step shape is present between the press-fit portion 84 and the fitting portion 85. A maximum terminal width W41 of the press-fit portion 84 is larger than the hole diameter Q of the through hole 35c. The fitting portion 85 has a fitting surface 85a as a step shape at a boundary portion with the press-fit portion 84, and a maximum terminal width W42 at the position of the fitting surface 85a is larger than the maximum terminal width W41 of the press-fit portion 84.

As a difference from the press-fit terminal 40 of the first embodiment, the connecting portion 83 of the press-fit terminal 80 has a flat plate shape with a constant terminal thickness in a side view. That is, the connecting portion 83 has flat surfaces 83a and 83b parallel to each other on the respective sides of the terminal in the thickness direction. In addition, a penetration hole 83c penetrating from the flat surface 83a to the flat surface 83b is formed at the center of the connecting portion 83 instead of a bottomed recess. Similarly to the recess 43c of the press-fit terminal 40 of the first embodiment, the penetration hole 83c is provided as a thinning shape for facilitating deformation of the connecting portion 83.

The press-fit portion 84 and the fitting portion 85 of the press-fit terminal 80 have the same functions as those of the press-fit portion 44 and the fitting portion 45 of the press-fit terminal 40 of the first embodiment. When the press-fit terminal 80 is connected to the substrate 35, the press-fit portion 84 is press-fitted into the through hole 35c in a deformed state where the terminal width becomes equal to or less than the hole diameter Q.

When the press-fit terminal 80 is inserted into the through hole 35c, the fitting portion 85 passes through the through hole 35c while reducing the terminal width through elastic deformation, and, after passing through the through hole 35c, the fitting portion 85 is restored from the elastic deformation so that the fitting surface 85a faces and fits to the upper surface 35b of the substrate 35. As a result, the movement of the press-fit terminal 80 with respect to the substrate 35 in the detachment direction F2 is restricted.

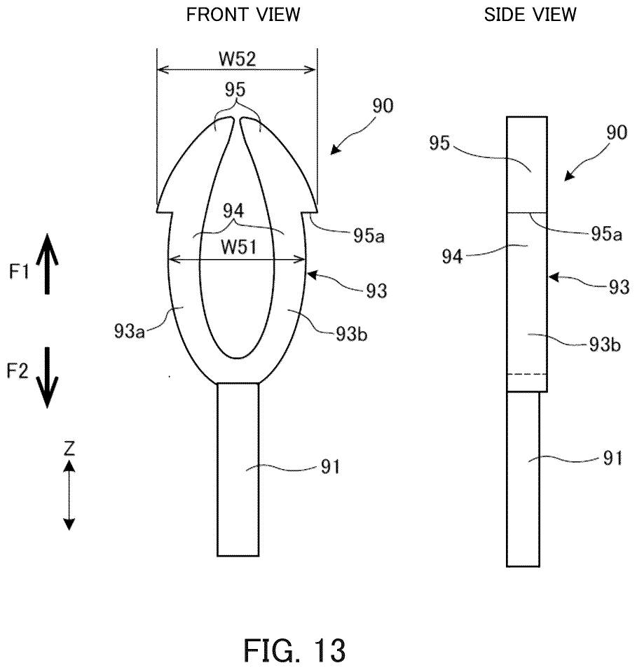

FIG. 13 illustrates a press-fit terminal 90 of a sixth embodiment. FIG. 13 illustrates the press-fit terminal 90 in an initial state before being connected to the substrate 35. A base portion 91 of the press-fit terminal 90 has the same configuration and role as those of the base portion 41 of the press-fit terminal 40 of the first embodiment, and a detailed description thereof will be omitted.

A connecting portion 93 of the press-fit terminal 90 is different from the press-fit terminal of each of the above-described embodiments in that the shape in a front view is a forked structure having a separated distal end (Q-shaped in the front view). The connecting portion 93 has a flat plate shape with a constant terminal thickness in a side view. The connecting portion 93 has a pair of arms 93a and 93b having a substantially symmetrical shape disposed at an interval in the terminal width direction. The pair of arms 93a and 93b are connected at the position of the base portion 91.

In the connecting portion 93, a portion of the pair of arms 93a and 93b on a proximal end side constitutes a press-fit portion 94, and a portion on a distal end side constitutes a fitting portion 95. A maximum terminal width W51 of the press-fit portion 94 is larger than the hole diameter Q of the through hole 35c. The fitting portion 95 has a step-shaped fitting surface 95a at a boundary portion with the press-fit portion 94 in each of the pair of arms 93a and 93b. A maximum terminal width W52 of the fitting portion 95 at the position of the fitting surface 95a is larger than a maximum terminal width W51 of the press-fit portion 94. The width of the distal end portion of the fitting portion 95 is smaller than the hole diameter Q of the through hole 35c, so that the distal end side of the fitting portion 95 can be inserted first into the through hole 35c.

The press-fit portion 94 and the fitting portion 95 of the press-fit terminal 90 have the same functions as those of the press-fit portion 44 and the fitting portion 45 of the press-fit terminal 40 of the first embodiment. When the press-fit terminal 90 is inserted into the through hole 35c, the connecting portion 93 is elastically deformed so as to reduce the interval between the pair of arms 93a and 93b. Then, when the press-fit terminal 90 is connected to the substrate 35, the press-fit portion 94 is press-fitted into the through hole 35c in a deformed state where the terminal width becomes equal to or less than the hole diameter Q.

When the press-fit terminal 90 is inserted into the through hole 35c, the fitting portion 95 passes through the through hole 35c while making the terminal width smaller than the maximum terminal width W52 through elastic deformation, and, after passing through the through hole 35c, the fitting portion 95 is restored from the elastic deformation so that the fitting surface 95a faces and fits to the upper surface 35b of the substrate 35. As a result, the movement of the press-fit terminal 90 with respect to the substrate 35 in the detachment direction F2 is restricted.

Due to a structure in which the distal end sides of the pair of arms 93a and 93b are not connected, the press-fit terminal 90 is easily deformed in the terminal width direction, and the press-fit load can be reduced.

Although not illustrated in FIGS. 12 and 13, it is preferable to provide the support portion 46 (FIG. 4) and the support portion 67 (FIG. 10) on the wall 25 of the press-fit terminal 80 of the fifth embodiment and the press-fit terminal 90 of the sixth embodiment to determine an appropriate insertion amount in the insertion direction F1.

Although the above-described embodiments are examples of application to the press-fit terminal protruding from the wall 25 of the case member 4, the present invention can also be applied to terminal structures of other portions of the semiconductor device 1.

In addition, the press-fit terminal and the terminal structure of the present invention can also be applied to electronic devices other than power semiconductor modules.

Although the entire connecting portion of the press-fit terminal is configured to be elastically deformable in the above-described embodiments, the invention is not limited thereto. For example, the elastically deformable configuration may be selected for the fitting portion that needs to be fitted by restoring the shape after passing through the through hole, and a plastically deformable configuration may be selected for the press-fit portion where the state of being press-fitted into the through hole is to be maintained.

Although the embodiments and the modifications have been described above, the above-described embodiments and modifications may be wholly or partially combined as another embodiment.

In addition, the present invention is not limited to the above-described embodiments and modifications, and various changes, substitutions, and modifications may be made without departing from the spirit of the technical idea. Further, when the technical idea can be realized in another manner by the progress of the technology or another derived technology, the technical idea may be carried out by using a method thereof. Therefore, the claims cover all implementations that may be included within the scope of the technical idea.

The features of the above-described embodiments will be summarized below.

A press-fit terminal according to the above-described embodiments is a press-fit terminal connected to a substrate having a through hole, the press-fit terminal including: a press-fit portion press-fitted and held inside the through hole; and a fitting portion that fits to an outer surface of the substrate outside the through hole and restricts movement of the press-fit terminal in a direction in which the press-fit terminal comes off from the through hole.

In the press-fit terminal according to the above-described embodiments, a size of the fitting portion in a radial direction of the through hole is larger than a size of the press-fit portion, the fitting portion has a step-shaped fitting surface between the fitting portion and the press-fit portion, and the fitting surface faces the outer surface of the substrate.

The press-fit terminal according to the above-described embodiments further includes a groove between the fitting portion and the press-fit portion, the fitting portion has a fitting surface on an inner surface of the groove, and the fitting surface faces the outer surface of the substrate.

The press-fit terminal according to the above-described embodiments further includes a second fitting portion that fits to a second outer surface on an opposite side of the outer surface of the substrate outside the through hole to restrict movement of the press-fit terminal in a direction in which the press-fit terminal is inserted into the through hole.

In the press-fit terminal according to the above-described embodiments, a size of the second fitting portion in a radial direction of the through hole is larger than a size of the press-fit portion, the second fitting portion has a step-shaped second fitting surface between the fitting portion and the press-fit portion, and the second fitting surface faces the second outer surface of the substrate.

The press-fit terminal according to the above-described embodiments further includes a groove between the second fitting portion and the press-fit portion, the fitting portion has a second fitting surface on an inner surface of the groove, and the second fitting surface faces the second outer surface of the substrate.

The terminal structure according to the above-described embodiments further includes a support portion that is provided in an electronic component including the press-fit terminal, and is in contact with a second outer surface on the opposite side of the outer surface of the substrate to restrict movement of the press-fit terminal in a direction in which the press-fit terminal is inserted into the through hole.

The semiconductor module according to the above embodiment includes a plurality of semiconductor elements and the terminal structure.

### INDUSTRIAL APPLICABILITY

As described above, the present invention has an effect of obtaining a press-fit terminal that can be easily press-fitted into the through hole and can be reliably prevented from coming off from the through hole, and is particularly useful for industrial or electrical semiconductor devices or the like.

The present application is based on Japanese Patent Application No. 2022-180715 filed on Nov. 11, 2022. All the contents are included herein.

### REFERENCE SIGNS LIST

1 Semiconductor device (semiconductor module)
2 Unit module
3 Cooler
4 Case member
5 Sealing resin
6 Insulating substrate
7 Semiconductor element
8 Base plate
10 Metal wiring plate
16 P terminal
17 N terminal
18 M terminal
19 Internal wiring
20 Insulating plate
21 Heat dissipation plate
22 Circuit board
35 Substrate
35a Lower surface (second outer surface)
35b Upper surface (outer surface)
35c Through hole
40 Press-fit terminal
41 Base portion
42 Guide portion
43 Connecting portion
44 Press-fit portion
45 Fitting portion
45a Fitting surface
46 Support portion
50 Press-fit terminal
51 Base portion
52 Guide portion
53 Connecting portion
54 Press-fit portion
55 Fitting portion
55a Fitting surface
56 Second fitting portion
56a Second fitting surface
60 Press-fit terminal
61 Base portion
62 Guide portion
63 Connecting portion
64 Press-fit portion
65 Fitting portion
65a Fitting surface
66 Groove
67 Support portion
70 Press-fit terminal
71 Base portion
72 Guide portion
73 Connecting portion
74 Press-fit portion
75 Fitting portion
75a Fitting surface
76 Second fitting portion
76a Second fitting surface
77 Groove
78 Groove
80 Press-fit terminal
81 Base portion
82 Guide portion
83 Connecting portion
84 Press-fit portion
85 Fitting portion
85a Fitting surface
90 Press-fit terminal
91 Base portion
93 Connecting portion
93a Arm
93b Arm
94 Press-fit portion
95 Fitting portion
95a Fitting surface
F1 Insertion direction
F2 Detachment direction
Q Hole diameter

1. A press-fit terminal to be connected to a substrate having a through hole, the press-fit terminal comprising:
a press-fit portion configured to be press-fitted and held inside the through hole; and
a fitting portion configured to fit to an outer surface of the substrate outside the through hole and restrict movement of the press-fit terminal in a direction in which the press-fit terminal comes off from the through hole.

2. The press-fit terminal according to claim 1, wherein a length of the fitting portion in a radial direction of the through hole is larger than a length of the press-fit portion, such that the fitting portion has a step-shaped fitting surface between the fitting portion and the press-fit portion, the fitting portion being configured so that the fitting surface abuts the outer surface of the substrate.

3. The press-fit terminal according to claim 1, further comprising a groove between the fitting portion and the press-fit portion, wherein the fitting portion has a fitting surface formed by an inner surface of the groove and is configured so that the fitting surface abuts the outer surface of the substrate.

4. The press-fit terminal according to claim 1, wherein the fitting portion is a first fitting portion, and the outer surface of the substrate is a first outer surface, the press-fit terminal further comprising a second fitting portion configured to fit to a second outer surface of the substrate outside the through hole, the second outer surface being opposite to the first outer surface of the substrate, the second fitting portion being configured to restrict movement of the press-fit terminal in a direction in which the press-fit terminal is inserted into the through hole.

5. The press-fit terminal according to claim 4, wherein a length of the second fitting portion in a radial direction of the through hole is larger than a length of the press-fit portion such that the second fitting portion has a step-shaped second fitting surface between the second fitting portion and the press-fit portion, the second fitting portion being configured so that the second fitting surface abuts the second outer surface of the substrate.

6. The press-fit terminal according to claim 4, further comprising a groove between the second fitting portion and the press-fit portion, wherein the fitting portion has a second fitting surface formed by an inner surface of the groove, and is configured that the second fitting surface abuts the second outer surface of the substrate.

7. A terminal structure provided in an electronic component, the terminal structure comprising:
a substrate having a first outer surface and a second outer surface opposite to each other, and a through hole penetrating through the substrate from the first outer surface to the second outer surface;
a press-fit terminal inserted into the through hole of the substrate from the second outer surface to the first outer surface, and including:
a press-fit portion press-fitted and held inside the through hole, and
a fitting portion fitted to the first outer surface of the substrate and restricting movement of the press-fit terminal in a direction in which the press-fit terminal comes off from the through hole; and
a support portion that is in contact with the second outer surface and restricts movement of the press-fit terminal in a direction in which the press-fit terminal is inserted into the through hole.

8. A semiconductor module comprising: a plurality of semiconductor elements; and the terminal structure according to claim 7, the terminal structure being electrically connected to one of the plurality of semiconductor elements.
